(19) United States
(12) Patent Application Publication
(10) Pub. No.: US 2006/0088086 A1
(43) Pub. Date: Apr. 27, 2006

(54) Reverse scaling for improved bandwidth in equalizers

(75) Inventors: Srikanth Gondi, Los Angeles, CA (US); Yoshinori Nishi, Sunnyvale, CA (US)

Correspondence Address: OLIFF & BERRIDGE, PLC, P.O. BOX 19928, ALEXANDRIA, VA, 22320, US

(73) Assignee: KAWASAKI MICROELECTRONICS AMERICA, INC., San Jose, CA (US)

(21) Appl. No.: 11/214,910

(22) Filed: Aug. 31, 2005

Related U.S. Application Data
(60) Provisional application No. 60/621,535, filed on Oct. 25, 2004.

(51) Int. Cl. H03H 7/30

(52) U.S. Cl. 375/229

(57) ABSTRACT

An equalizer may use reverse scaling of physical dimensions between a plurality of equalizer stages to improve overall bandwidth. The equalizer may provide 20 dB of peaking at 5 GHz with good linearity and little noise accumulation, using CMOS technology.

### RELATED APPLICATIONS

This non-provisional application claims the benefit of U.S. Provisional Application No. 60/621,535 filed Oct. 25, 2004, and is related to U.S. application Ser. No. ______ (Attorney Docket No. 121447) and U.S. application Ser. No. ______ (Attorney Docket No. 121448), each of which is incorporated by reference in its entirety.

### BACKGROUND

This invention relates to systems and methods for improving the bandwidth in equalizers.

Data which is transmitted through a communications channel suffers from distortion due to the frequency-dependent transmission properties of the channel. Skin effect losses and dielectric losses are common examples of frequency-dependent channel losses which can be imposed on the signal passing through the channel. The distortion of the signal at high frequencies can lead to intersymbol interference (ISI), wherein the rising edge of a subsequent data bit is superimposed on the falling edge of the previous data bit, leading to a smearing of the transition between bits. This smearing causes increased timing jitter and reduced amplitude. The increased timing jitter makes clock recovery more difficult, whereas the reduced amplitude degrades the bit error rate performance of the channel at the output.

The frequency-dependent losses may, in theory, be compensated by applying either a precompensation to the signal before the channel, or a frequency-dependent gain, or boost, to the signal at the exit of the channel. Precompensation adjusts the attributes of the input signal at the transmitter to compensate for known transmission properties of the channel. However, since the transmission properties of the channel are often not known a priori, the compensation is more commonly applied to the output of the channel as receiver equalization, referred to herein as equalization.

Equalizers adjust the output signal from a channel to reverse some of the effect of distortion of the channel on the data signal. Equalizers apply a frequency-dependent amplification to the signal, such that frequencies which have been transmitted with high loss are amplified relative to frequencies which have been transmitted with low loss.

### SUMMARY

However, at very high frequencies, the limited gain-bandwidth product of the technology limits the amount of boost that can be applied to a signal in a given frequency range. Equalizers in the multi-Gb/sec range have traditionally been implemented using expensive bipolar-CMOS technology. This makes high frequency equalizers very difficult to implement in cost-constrained, noisy environments, such as in microprocessors and memories on printed circuit boards (PCBs), backplane environments with a multitude of PCBs, server and networking equipment transferring data, and gigabit Ethernet applications.

A 10 Gb/sec equalizer may be fabricated using all CMOS processes. An improved bandwidth may be achieved by scaling down a size of structures in each stage of the equalizer by a predefined amount. A reduced capacitance of the scaled-down structures may reduce the resistance x capacitance (RC) time constant for each stage by the predefined amount, which may improve an overall bandwidth of the equalizer.

The 10 Gb/sec equalizer may comprise a multi-stage equalizer having at least one boost stage and at least one gain stage. The at least one gain stage may amplify an output of at least one boost stage. The at least one gain stage may have an input capacitance lower than an input capacitance of a previous boost stage by a predetermined scale factor, β.

Various details are described in, or are apparent from, the following detailed description.

### BRIEF DESCRIPTION OF THE DRAWINGS

Various details are described with reference to the following figures, wherein:

FIG. 1 is a diagram of an exemplary equalizer operating in a data detection circuit;

FIG. 2 is a diagram of an exemplary equalizer comprising n stages;

FIG. 3 is a diagram of an exemplary equalizer using reverse scaling;

FIG. 4 shows an exemplary five-stage equalizer with reverse scaling;

FIG. 5 shows further details of an exemplary boost stage of the five-stage equalizer of FIG. 4;

FIG. 6 shows further details of an exemplary gain stage of the five-stage equalizer of FIG. 4;

FIG. 7 illustrates a channel width dimension of an exemplary CMOS transistor;

FIG. 8 illustrates a scaled channel width dimension of the exemplary CMOS transistor of FIG. 7;

FIGS. 9-12 show measured results of the equalizer of FIG. 4 using a power supply at 1.2V;

FIGS. 13-16 show measured results of the equalizer of FIG. 4 using a power supply at 1.0V; and

FIG. 17 shows a photograph of the equalizer die.

### DETAILED DESCRIPTION OF EXEMPLARY EMBODIMENTS

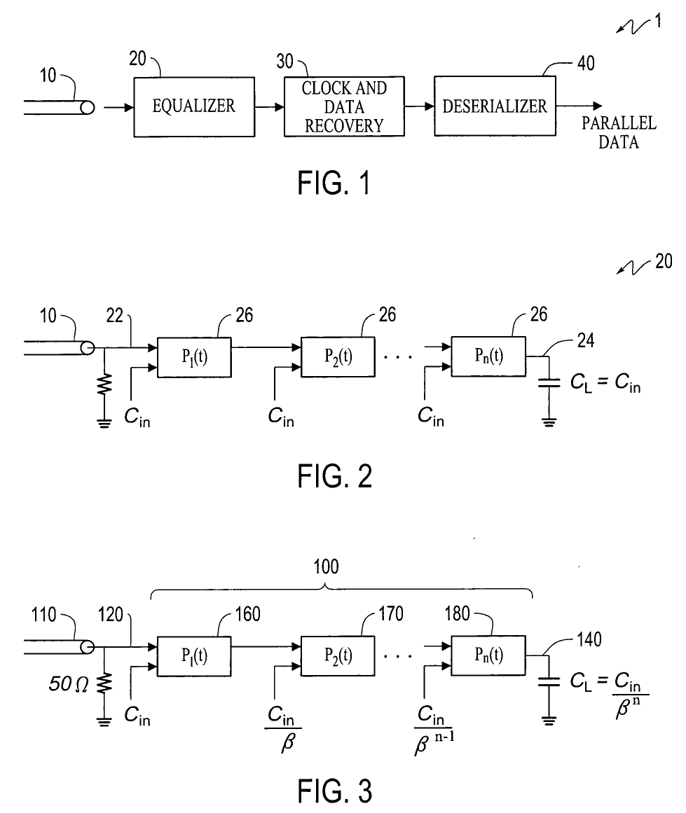

FIG. 1 is a diagram of an equalizer operating in a data detection circuit 1. Data may be transmitted over a channel 10, and the data signal may be distorted by the transmission characteristics of the channel. In particular, high frequency components, for example, frequencies in excess of 500 MHz of the data signal may be attenuated, whereas low frequency components, for example, frequencies lower than 500 MHz, may pass through the channel with relatively little loss. As a result, an equalizer 20 may be placed in the data detection circuit 1, to provide gain (boost) to the high frequency components. After the equalizer 20, a clock and data recovery circuit 30 may accept the equalized signal and recover a data clock based on the equalized signal. For example, a phase-locked loop may be employed to generate a clock based on zero-crossings of the equalized data signal. The equalized data signal may then be sampled according to the occurrence of the data clock pulses, and the samples may be compared to a threshold, to determine if a bit is present, and, when present, the digital value of the bit. The data may then be transmitted to a data deserializer 40, that may arrange the data in a parallel format and may output the parallel data on parallel lines.

FIG. 2 is a diagram of an exemplary equalizer implementation which may be used in the data detection circuit 1 in FIG. 1. Equalizer 20 may use a plurality of n-stages 26 to accomplish equalization of an input signal 22, from channel 10, to provide an output signal 24 to drive a load capacitance C_{L}. Multiple stages 26 are used in equalizer 20 to obtain a required amount of high frequency gain for clock and data recovery circuit 30 of FIG. 1. Because equalizer 20 of FIG. 2 does not use reverse scaling, the input capacitance of each of the n stages 26 is identical. If n such identical stages 26 are cascaded as shown, the small signal bandwidth BWₒᵥₑᵣₐₗₗ of the equalizer 20 drops considerably, according to the equation:

$${BW}_{overall} = {BW}_{0} \sqrt{{2}^{\frac{1}{n}} - 1} . \qquad ( 1 )$$

where BW₀ is the bandwidth of a single stage and n is the number of stages. When n=5, for example, the bandwidth may be reduced by a factor of about 2.6. This reduction of small signal bandwidth significantly impedes the ability of such an equalizer to amplify frequency components at multi-Gb/sec frequencies.

However, the input capacitance of each stage may be scaled down by a scale factor, referred to herein as “reverse scaling”. As a result, the time constant of the output node of each stage may be reduced by a factor that depends on the scale factor applied to succeeding stages. Design considerations for choosing and implementing a scale factor are discussed in further detail below.

FIG. 3 is a diagram of an exemplary equalizer 100 using reverse scaling. The equalizer 100 may accept a signal 120 from a transmission line 110, and may output a signal 140 across a load capacitance C_{L}. N-equalizer stages 160-180 of equalizer 100 may each have an input capacitance which is reduced by a scale factor of β compared to the preceding stage. A final load capacitance C_{L} in such a case is

$${C}_{L} = \frac{{C}_{in}}{{β}^{n}} . \qquad ( 2 )$$

where Cᵢₙ is the input capacitance, n is the number of stages, and β is the scale factor for the capacitance between each stage. Equation (1) can be rewritten to give an expression for the scale factor β in terms of Cᵢₙ and C_{L} according to

$$β = {( \frac{{C}_{in}}{{C}_{L}} )}^{\frac{1}{n}} . \qquad ( 3 )$$

According to equation (3), the scale factor may be determined by the input capacitance Cᵢₙ, the desired output capacitance C_{L}, and the number of stages n. The input capacitance Cᵢₙ in turn, may be limited by the requirement to minimize, or at least reduce, the amplitude of the reflected signal at the input to the equalizer 100, which is reflected back into the transmission line 110. Given an input resistance of the equalizer 100 is 50 Ω, and a desire to have the reflected signal attenuated by at least 10 dB at 10 GHz compared to input signal 120, the highest tolerable input capacitance may be less than about 212.5 femtoFarads (fF). However, of this 212.5 fF capacitance budget, other sources of parallel capacitance may further reduce the tolerable capacitance of the input stage. For example, assuming that some capacitance exists on the input pads and in the structures implemented in the circuit to protect the circuit from electrostatic discharge (ESD), these capacitances consume at least about 125 fF of the 212.5 fF input capacitance budget. As a result, the input capacitance of the circuit may be required to be less than about 87.5 fF.

The value of the scale factor β for a given application may depend, in general, on the number of stages required to achieve a level of boost required for the system. The number of stages used may be based on an overall gain required of the equalizer, and a gain x bandwidth product of each stage. Although not required, it may be advantageous to have the scale factor β be the same for each of the stages, in order to minimize any mismatch in RC time constants for each node.

Because the load capacitance C_{L} may be determined by a factor βⁿ according to equation (2), the bandwidth of the system may be increased, because a lower capacitance reduces the RC time constant of the output node. It can be shown that a bandwidth BW₁₀₀ of the equalizer 100 shown in FIG. 3, compared to a bandwidth BW₁ of equalizer 20 shown in FIG. 2, is given by

$$\frac{{BW}_{100}}{{BW}_{1}} = {( \frac{{C}_{in}}{{C}_{L}} )}^{\frac{1}{n}} \frac{\sqrt{{2}^{\frac{1}{n + 1}} - 1}}{\sqrt{{2}^{\frac{1}{n}} - 1}} = β \frac{\sqrt{{2}^{\frac{1}{n + 1}} - 1}}{\sqrt{{2}^{\frac{1}{n}} - 1}} \qquad ( 4 )$$

Comparison of equation (4) with equation (3) reveals that an improvement in the bandwidth may be proportional to the scale factor β. Using, for example, five stages, a load capacitance of 20 fF, and an input capacitance of 75 fF, an improvement in bandwidth of equalizer 100 compared to equalizer 1 may be greater than 20%, as BW₁₀₀/BW₁ is approximately 1.25. The scale factor β for this situation may be about 1.3.

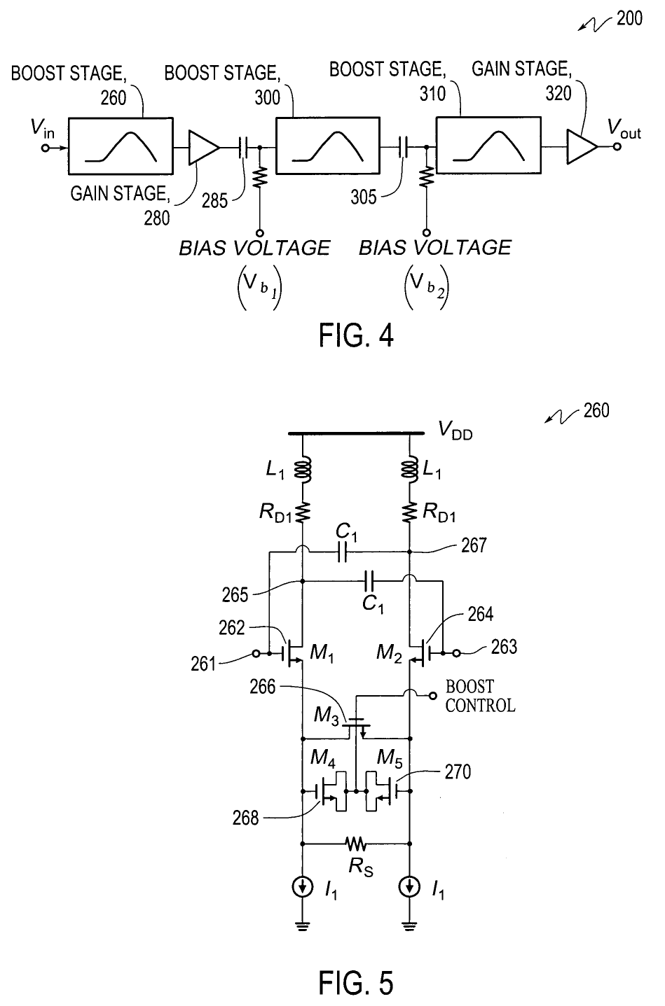

FIG. 4 is a circuit diagram of another exemplary equalizer 200 using reverse scaling. The exemplary equalizer 200 may include three boost stages 260, 300 and 310, interspersed with two gain stages 280 and 320. The boost stages 260, 300 and 310 may each have a frequency response which is controlled by a boost control signal, as explained further below. Gain stages 280 and 320 may apply frequency independent gain to an output of the boost stages 260 and 310. Gain stage 280 may amplify the output of boost stage 260, and gain stage 320 may amplify respectively the output of boost stage 310. An input capacitance of each boost or gain stage may be designed to be lower than an input capacitance of the previous gain or boost stage, for example, by the scale factor β.

As shown in FIG. 4, coupling capacitors 285 and 305 may be disposed between any or all stages of the equalizer 200. For example, coupling capacitor 285 is shown between gain stage 280 and boost stage 300, and coupling capacitor 305 is shown between boost stage 300 and boost stage 310. However, it should be understood that this layout is exemplary only, and that coupling capacitors may be placed in other locations as well. The function of the coupling capacitors is to isolate the DC components of the signal between stages. Therefore, the bias voltage of the two stages, V_{b1} and V_{b2}, can be different and hence alleviate headroom issues. By reducing the signal amplitude at low frequencies, the voltage “headroom” of the equalizer may be improved, that is, the amount of gain which may be applied to a signal is not compromised by a large DC offset. The lower cutoff frequency of the coupling capacitors implemented in the circuit as shown in FIG. 4 may be below 10 MHz. The total output noise voltage may be, according to simulation, less than or equal to 9 mVᵣₘₛ.

FIG. 5 is an exemplary circuit diagram of the boost stage 260 of FIG. 3. Each boost stage 260 may include at least 5 transistors: input transistor M1 262, input transistor M2 264, and transistors M3 266, M4 268 and M5 270. Transistor M3 266 may act as a variable resistor, and transistors M4 268 and M5 270 may act as varactors, as explained further below. The transistors M1 262, M2 264, M3 266, M4 268 and M5 270 may be arranged as in a source degeneration structure, wherein the tuning of the circuit is based on changes in capacitance of the M4 268 and M5 270 transistors. Along with inductors L1, the resistance and capacitance in the circuit cause the circuit to have a characteristic frequency response. Changing values of the resistance and capacitance changes the characteristic frequency response of the circuit. The resistance and capacitance of the circuit may be changed by adjusting the boost control signal, as described below.

A differential input signal may be input to nodes 261 and 263 to input transistors M1 262 and M2 264, respectively. The output from the circuit may be taken from nodes 265 and 267. The frequency characteristics of the circuit may be tuned by adjusting the resistance across transistor M3 166, for example, by adjusting the gate voltage on M3 266, via the boost control signal. The boost control signal may also be applied to drain terminals of transistors M4 268 and M5 270. Variation in the gate-to-drain voltage may change the capacitance of transistors M4 268 and M5 270, such that transistors M4 268 and M5 270 act as voltage-variable capacitors, or varactors. Accordingly, the boost control may alter the shape and position of the frequency response characteristics of the circuit 260, for example, by changing the resistance of M3 266 and the capacitance of M4 268 and M5 270. In other words, changing the resistance and capacitance of M3 266, M4 268 and M5 270 may move the zero of the transfer function for the boost stage 260. Accordingly, the boost may be provided by capacitive degeneration, by tuning the frequency characteristics of boost stage 260, for example, by adjusting the capacitance of transistors M4 268 and M5 270.

The high frequency boost of the boost stage 260 may be about 8 dB with a 10 GHz bandwidth, and with good linearity. However, the boost stage 260 may be lossy at low frequencies, for example, frequencies lower than about 500 MHz.

The input capacitance of the boost stage may be determined primarily by the capacitance of input transistors M1 262 and M2 264. The capacitance of these transistors may be determined by the physical dimensions of the transistors. For example, using 0.13 μm CMOS lithography, constructing the input transistors M1 262 and M2 264 to have a channel width of about 36 μm may result in an input capacitance on each input node 261 and 263 of about 75 fF, which meets the reflection requirements discussed above.

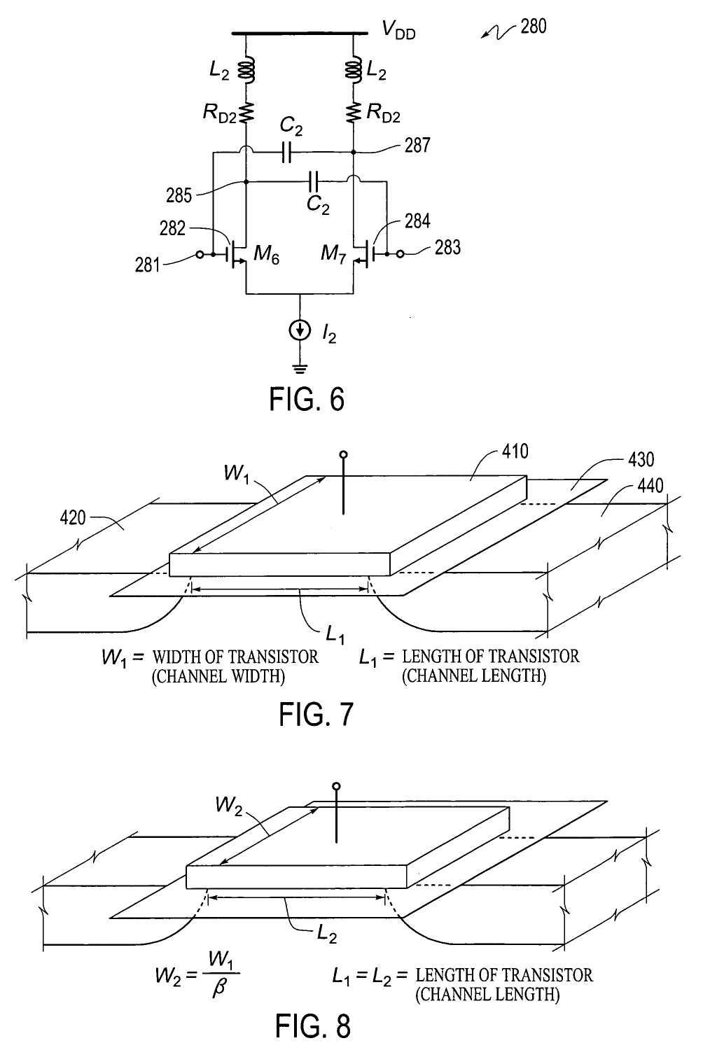

FIG. 6 shows exemplary details of the gain stage 280. Gain stage 280 may include at least two transistors M6 282 and M7 284. The differential input signal may be applied to input nodes 281 and 283, respectively, from output nodes 265 and 267 of boost stage 260 of FIG. 4. The output from gain stage 280 may be taken from nodes 285 and 287, which may then be input to the next boost stage 300 (see FIG. 3). Gain stage 280 may provide a frequency independent gain of about 1.7 to 1.8, or of approximately 2, across all frequencies. The amount of gain provided by gain stage 280 may be a function of the size of M6 282 and M7 284, the resistance value R_{D2}, and the amplifier bias current I2.

Reverse scaling may be applied to gain stage 280 by scaling the physical dimensions of gain stage 280 by the scale factor β. An exemplary approach is shown in FIGS. 7 and 8. FIG. 7 shows a typical CMOS transistor comprising a gate 410 which turns on a current between a source region of electrons 420 and a drain region 440 of electrons formed in substrate 430, for example, by applying a field to the channel region 430. A capacitor may be formed between gate 410 and channel region L₁. The width of gate 410 shown in FIG. 7 is W₁. By reducing the width of the gate W₁ to a narrower width W₂=W₁/p, as shown in FIG. 8, the capacitance of the gate/channel region may be reduced proportionately.

With reverse scaling, reduced physical dimensions tend to increase the value of the resistance R_{D2}, reducing the value of I2, and reducing the capacitance of the M6 282 and M7 284 transistors. Since the resistance of R_{D2} increases but the amplifier current I2 drops, the gain of the gain stage 280 may be approximately unchanged by the reduction in physical dimension. However, the input capacitance may drop in proportion to the reduced dimension. For example, reducing the width of the channel between the gate terminal and source terminal of M6 282, may reduce the capacitance of transistor M6 282 proportionally, as illustrated in FIGS. 7 and 8. The RC time constant of the output nodes 265 and 267 therefore may drop in proportion to the reduction of capacitance of M6 282 and M7 284, respectively. For example, the channel width of the transistors M6 282 and M7 284 may be made to be about 24 μm, resulting in an output capacitance of about 60 fF.

Although the RC time constant may be reduced, as described above, by reducing the input capacitance of transistors M6 282 and M7 284, it should be understood that the RC time constant may also be reduced by reducing the resistance R_{D1} of the stage 260. However, since higher values of R_{D!} correspond to higher gains, which is desirable, the capacitance rather than the resistance may be reduced to reduce the RC time constant of the stage 260. The time constant of stage 280 is then defined by R_{D2} and the capacitance of the next stage (after 280).

Reverse scaling may then be applied to the remaining stages 300, 310 and 320 shown in FIG. 4, as described above with respect to FIGS. 5 and 6. One exemplary embodiment of the CMOS equalizer 200 has the physical dimensions shown in Table 1, below.

TABLE 1

| Stage number | Type | Channel width | Lithography linewidth |
|---|---|---|---|
| Stage 1 | Boost stage | 36 μm | 0.13 μm |
| Stage 2 | Gain stage | 24 μm | 0.13 μm |
| Stage 3 | Boost stage | 16 μm | 0.13 μm |
| Stage 4 | Boost stage | 14 μm | 0.13 μm |
| Stage 5 | Gain stage | 12 μm | 0.13 μm |

The dimensions given in Table 1 result from applying a scale factor β of about 1.3. The overall improvement in bandwidth for this equalizer, compared to an equalizer without using reverse scaling, may be at least about 20%. This improvement may be necessary to enable the equalizer to operate effectively at 10 Gb/sec.

It should be understood that the values given in Table 1 are exemplary only, and other values of the scale factor β and the channel widths may be chosen, such as values greater than 1.0, which may render a corresponding improvement in overall bandwidth for the equalizer.

The three boosting stages and two gain stages of the equalizer shown in FIGS. 4-6 may provide 20 dB of peaking at 5 GHz with good linearity and little noise accumulation in the stages.

FIGS. 9-12 show experimental results of an equalizer using reverse scaling on a signal having a maximum data rate of 10 Gb/sec. The supply voltage for FIGS. 9-12 was 1.2V. FIG. 9 shows the 10 Gb/sec signal at the output of a 30 inch channel, and FIG. 11 shows the 10 Gb/sec signal at the output of a 6 inch channel. The channels were fabricated using Flame Retardant 4 (FR4), a fiberglass material widely used in the manufacture of printed circuit boards. As shown in FIGS. 9 and 11, the 30 inch channel may significantly attenuate the high frequency attributes of the signal, leading to severe intersymbol interference, and the 6 inch channel may similarly attenuate the high frequency attributes, although less severely. The signal shown in FIG. 9, if put into a clock recovery circuit, may result in significant phase jitter of the clock.

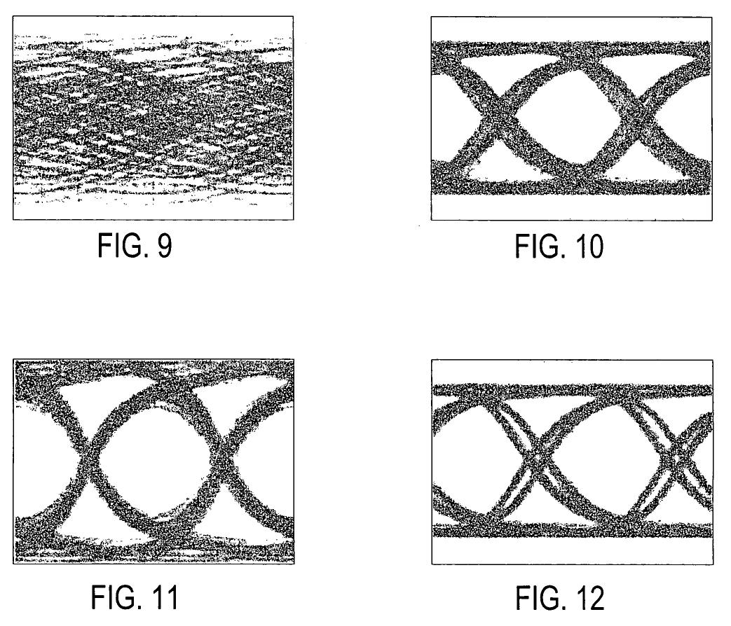

FIGS. 10 and 12 show the signals from FIGS. 9 and 11, respectively, after equalization in an equalizer using reverse scaling, such as that shown in FIG. 4. As shown in FIGS. 10 and 12, the high frequency characteristics of the signal may be largely restored by the equalizer, leading to much improved bit error rate performance at the data detector.

FIGS. 13-16 also show experimental results of an equalizer using reverse scaling on a signal having a maximum data rate of 10 Gb/sec. The supply voltage for FIGS. 13-16 was 1.0 V, rather than the 1.2 V shown in FIGS. 9-12. FIG. 13 shows the 10 Gb/sec signal at the output of a 30 inch FR4 channel, and FIG. 15 shows the 10 Gb/sec signal at the output of a 6 inch FR4 channel. As shown in FIGS. 13 and 15, the 30 inch channel may significantly attenuate the high frequency attributes of the signal, leading to severe intersymbol interference, and the 6 inch channel may similarly attenuate the high frequency attributes, although less severely. The signal shown in FIG. 13, if put into a clock and data recovery circuit such as that shown in FIG. 1, may result in significant phase jitter of the clock and a high error rate.

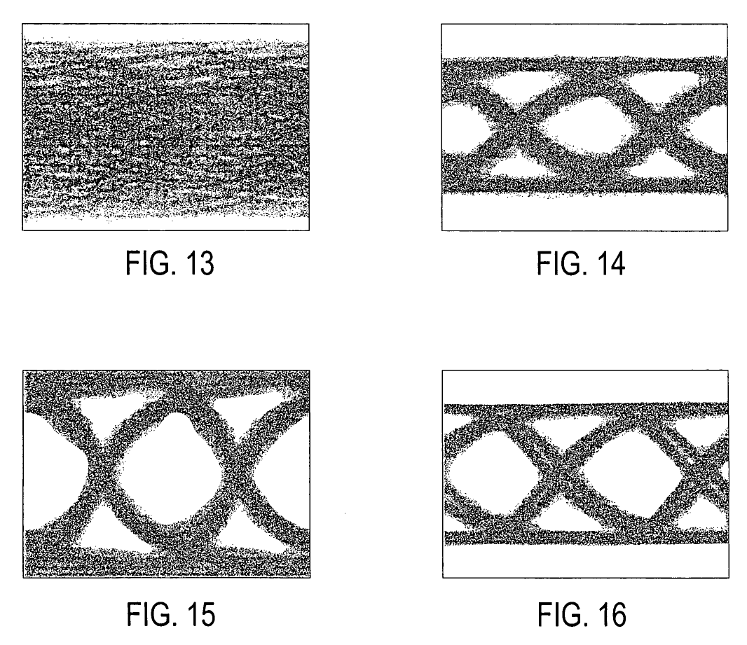

FIGS. 14 and 16 show the signals from FIGS. 13 and 15, respectively, after equalization in an equalizer using reverse scaling, such as that shown in FIG. 4. As shown in FIGS. 14 and 16, the high frequency characteristics of the signal may be largely restored by the equalizer, leading to much improved bit error rate performance at the data detector.

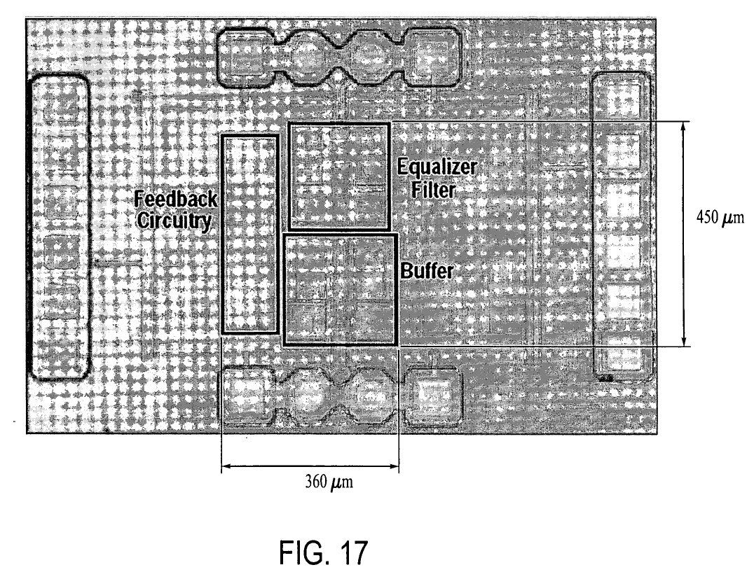

FIG. 17 is a photograph of the exemplary equalizer 200 taken through a microscope, the features having the characteristic dimensions shown in FIG. 17. As shown in FIG. 17, the overall size of the CMOS adaptive equalizer is about 450×360 μm, including the feedback and buffer structures. The equalizer filter itself occupies an area of only 225 μm×240 μm. Due to the relatively small size and low power consumption, the equalizer filter may be suitable for a variety of applications.

Table 2 summarizes some experimental performance results of the reverse scaling equalizer 200 shown in FIGS. 4-6.

TABLE 2

| Parameter | Value |
|---|---|
| Max data rate | 10 Gb/sec |
| Loss compensated | 20 dB @ 5 GHz |
| RMS noise | <9 mVᵣₘₛ |
| Power supply | 1.0-1.2 V |
| Power consumption | 16-25 mW |
| Die area | 450 μm × 360 μm |
| | (including feedback and buffer) |
| Technology | 0.13 μm CMOS |

While various details are described above in conjunction with the example outlined above, it is evident that many alternatives, modifications and variations are possible. For example, the reverse scaling techniques described herein are applicable to analog as well as digital equalizers. Accordingly, the exemplary implementations as set forth above are intended to be illustrative, not limiting.

What is claimed is:

1. A multi-stage equalizer, comprising:
at least one boost stage; and
at least one gain stage, that amplifies an output of the at least one boost stage, wherein the at least one gain stage has an input capacitance lower than an input capacitance of a previous boost stage by a predetermined scale factor β.

2. The multi-stage equalizer of claim 1, further comprising:
an output gain stage with an output node, wherein the output capacitance C_{L} of the output node of the output gain stage relative to an input capacitance Cᵢₙ of at least one of a first boost stage and a first gain stage is
$${C}_{L} = \frac{{C}_{in}}{{β}^{n}}$$
where n is a number of stages of the multi-stage equalizer.

3. The multi-stage equalizer of claim 1, wherein the scale factor β is greater than about 1.0.

4. The multi-stage equalizer of claim 2, wherein n is five, and the scale factor β is about 1.3.

5. The multi-stage equalizer of claim 2, wherein the input capacitance Cᵢₙ of the first boost stage or the first gain stage is less than or equal to about 100 fF.

6. The multi-stage equalizer of claim 2, wherein the output capacitance C_{L} relative to the input capacitance Cᵢₙ results in a bandwidth at least about 20% higher than a multi-stage equalizer in which the output capacitance C_{L} is equal to the input capacitance Cᵢₙ.

7. The multi-stage equalizer of claim 1, wherein the at least one boost stage and the at least one gain stage comprise complementary metal-oxide-semiconductor (CMOS) transistors.

8. The multi-stage equalizer of claim 7, wherein a channel width of at least one input transistor of the gain stage, is narrower that a channel width of at least one input transistor of a previous boost stage by the scale factor β.

9. The multi-stage equalizer of claim 7, wherein a channel width of at least one input transistor of the boost stage, is narrower than a channel width of at least one input transistor of a previous boost stage by the scale factor β.

10. The multi-stage equalizer of claim 1, the at least one boost stage further comprising at least three transistors that determine a frequency response of the at least one boost stage.

11. The multi-stage equalizer of claim 1, the at least one gain stage comprising at least two transistors that determine an input capacitance of the at least one gain stage.

12. The multi-stage equalizer of claim 1, wherein a ratio of a channel width of at least one transistor of the at least one gain stage to a channel width of at least one of the transistors of the previous boost stage defines the scale factor β.

13. The multi-stage equalizer of claim 10, wherein one of the at least three transistors comprises a variable resistor, and two of the at least three transistors comprise varactors.

14. The multi-stage equalizer of claim 13, wherein the frequency response of the boost stage is controlled by a boost control signal input to a gate terminal of one of the at least three transistors that comprises the variable resistor.

15. The multi-stage equalizer of claim 9, wherein the boost control signal is coupled to a drain terminal of each of the two of the at least three transistors that comprise varactors.

16. The multi-stage equalizer of claim 1, further comprising a clock and data recovery circuit that recovers data from an equalized signal.

17. A method of equalizing a signal from a channel, the method comprising:
boosting high frequency components of the signal in a first boost stage; and
amplifying the boosted signal in a gain stage having an input capacitance lower than that of the first boost stage by a predetermined scale factor β.

18. The method of claim 17, further comprising boosting the high frequency components in a second boost stage after amplification by the gain stage, wherein the second boost stage has a lower input capacitance than the gain stage.

19. The method of claim 18, further comprising:
outputting an equalized signal on an output node having a capacitance C_{L} lower than an input capacitance Cᵢₙ of the first boost stage by the scale factor β such that
$${C}_{L} = \frac{{C}_{in}}{{β}^{n}}$$
where n is a number of stages of the equalizer.

20. The method of claim 19, further comprising detecting transmitted data in the equalized signal.
